(19) United States
(12) Patent Application Publication
(10) Pub. No.: US 2007/0215335 A1
(43) Pub. Date: Sep. 20, 2007

(54) HEAT SINK

(76) Inventors: Chun-Chi Chen, Guangdong (CN); Shih-Hsun Wung, Guangdong (CN); Guang Yu, Guangdong (CN); Da-Yuan Zhou, Guangdong (CN); Jin-Biao Liu, Guangdong (CN)

Correspondence Address: NORTH AMERICA INTELLECTUAL PROPERTY CORPORATION, P.O. BOX 506, MERRIFIELD, VA, 22116, US

(21) Appl. No.: 11/308,239

(22) Filed: Mar. 14, 2006

(51) Int. Cl. H05K 7/20

(52) U.S. Cl. 165/185; 361/704

(57) ABSTRACT

A heat sink includes a base and a plurality of column-shaped fins. The base defines an array of blind holes therein. The fins threadedly engage in the base at the blind holes by self-tapping so that the fins are interferentially and intimately engaged with the base. The fins each include a head for facilitating to turn the fins, a terminated cone received in the blind holes and a spiral thread between the head and the terminated cone.

### FIELD OF THE INVENTION

The present invention relates generally to a heat sink, and more particularly to a heat sink comprising a base for removing heat from an electronic heat-generating component and a plurality of individual fins for dissipating the heat to the ambient environment.

### DESCRIPTION OF RELATED ART

Heat sinks are usually used to remove heat from electronic heat-generating components, such as central processing units (CPUs) etc., to keep the components in stable operation. A typical heat sink comprises a base for contacting a heat-generating component to absorb heat generated by the heat-generating component and a plurality of parallel planar fins attached to the base by soldering or adhering. The fins are used for dissipating the heat to the ambient environment.

To meet the requirement of removing heat from a more and more powerful heat-generating component, a current way is to enlarge the total heat-dissipation area of the fins by increasing the number of the fins or enlarging a dimension of each fin. However, above thermal resolutions are also limited by various factors; because in a computer enclosure, for instance, there are various components crowded in a small space, the space which can be available for the heat sink is mostly limited. The larger the number of the fins is, the denser the fins are, and further the narrower channels between the fins are. When the channels are too narrow, air is difficult to flow therethrough. For the same reason that there is merely a limited space available for the heat sink, enlarging the dimension of each fin is not quite feasible.

What is needed is a heat sink which has a great heat dissipating area without an increase of the number of the fins and without an enlargement of a dimension of each fin. Furthermore, the fins can be easily formed on the heat sink.

### SUMMARY OF INVENTION

A heat sink in accordance with a preferred embodiment of the present invention comprises a base and a plurality of column-shaped fins. The base defines an array of blind holes therein. The fins are screwed in the base at the blind holes by self-tapping so that the fins are interferentially and intimately engaged with the base. The fins each comprise a head for facilitating to turn the fins, a terminated cone received in a corresponding blind hole and a spiral thread between the head and the terminated cone. The spiral thread is a self-tapping screw thread.

Other advantages and novel features will become more apparent from the following detailed description of preferred embodiment when taken in conjunction with the accompanying drawings, in which:

### BRIEF DESCRIPTION OF DRAWINGS

FIG. 1 is an assembled view of a heat sink of a preferred embodiment in accordance with the present invention;

FIG. 2 is partially exploded view of FIG. 1; and

FIG. 3 is an enlarged isometric view of an individual fin of the heat sink of FIG. 1.

### DETAILED DESCRIPTION

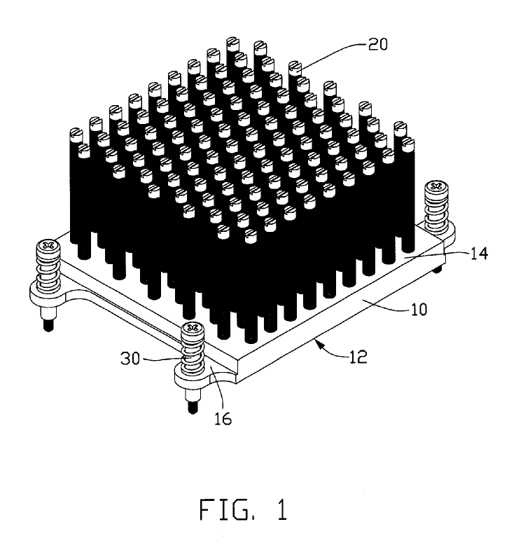

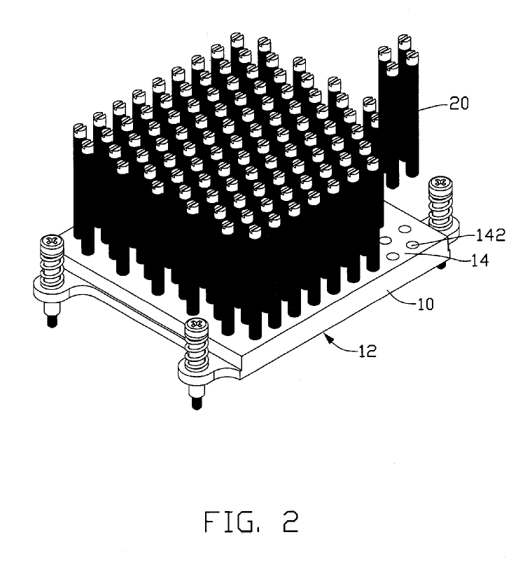

Referring to FIGS. 1-2, a heat sink in accordance with a preferred embodiment of the invention comprises a base 10 and a plurality of individual fins 20 which are threadingly mounted to the base 10.

The base 10 is a rectangular aluminum plate, and comprises a bottom surface 12 for absorbing heat from a heat-generating electronic component (not shown) and a top surface 14. Four locking ears 16 extend outwardly from four diagonal corners of the base 10 for receiving four fasteners 30, respectively. The fasteners 30 are used to secure the heat sink to a substrate (not shown) on which the electronic component is mounted. An array of blind holes 142 is drilled in the top surface 14 of the base 10, toward the bottom surface 12.

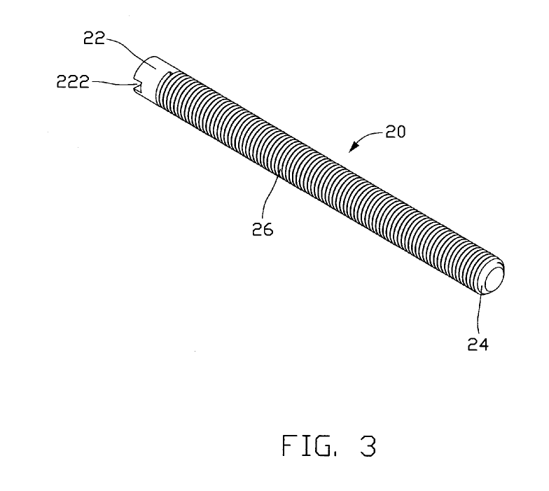

The fins 20 are column-shaped and are made of aluminum. Referring also to FIG. 3, each fin 20 comprises a head 22 and a terminated cone 24 at opposite ends thereof, respectively. An outer spiral thread 26 is formed on each fin 20 by a thread rolling process. The spiral thread 26 extends around a circumference of each fin 20, from the head 22 to the terminated cone 24. The head 22 defines a transverse groove 222 therein for receiving a tool (not shown), for example, a screwdriver, which is used to drive the fin 20 into a corresponding blind hole 142 of the base 10.

In order to mount the fins 20 to the base 10, the terminated cones 24 of the fins 20 are inserted into the blind holes 142 of the base 10. The tool (not shown) is inserted into the groove 222 of the head 22 of each fin 20, and is rotated to drive the fins 20 into the blind holes 142 of the base 10. The spiral thread 26 is a self-tapping screw thread. The base 10 is thus tapped by the spiral threads 26 at the blind holes 142 to form screw threads (not shown) therein for matching with the spiral threads 26 of the fins 20. Thus, the fins 20 are threadingly engaged into the blind holes 142 of the base 10.

In the preferred embodiment of the invention, each fin 20 is a column having the outer spiral thread 26 around the circumference thereof. This increases the heat dissipating area of the fins 20 without a need of enlarging a dimension of each fin 20 or of increasing the number of the fins 20. Additionally, the fins 20 is engaged to the base 10 by the fins 20 tapping the screw thread in the base 10 at the blind holes 142; thus, the fins 20 can interferentially and intimately engage with the base 10 at the blind holes 142. Heat resistance between the fins 20 and the base 10 is relatively smaller in comparison with a heat sink in which fins are attached to a base by soldering or adhering. Furthermore, the assembly of the fins 20 and the base 10 by the self-tapping is easier and more reliable than the soldering or adhering.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat sink comprising:
a base defining an array of blind holes therein; and
a plurality of column-shaped fins threadedly engaged in the base at the blind holes so that the fins are interferentially and intimately engaged with the base, the fins each comprising a head for facilitating to turn the fins, a terminated cone received in the blind holes and a spiral thread between the head and the terminated cone.

2. The heat sink as claimed in claim 1, wherein the head defines a transverse groove therein.

3. The heat sink as claimed in claim 1, wherein the spiral thread extends around a circumference of each fin, from the head to the terminated cone, and wherein the spiral thread is a self-tapping screw thread.

4. The heat sink as claimed in claim 1, wherein the base comprises a bottom surface adapted for absorbing heat from a heat-generating component and top surface opposite the bottom surface.

5. The heat sink as claimed in claim 4, wherein the blind holes are defined in the top surface of the base.

6. The heat sink as claimed in claim 1, wherein the base comprises four locking ears extending outwardly from four diagonal corners thereof, respectively.

7. The heat sink as claimed in claim 1, wherein the base is a rectangular aluminum plate.

8. The heat sink as claimed in claim 1, wherein the fins are made of aluminum.

9. A method of manufacturing a heat sink comprising the steps of:
providing a plate comprising a bottom surface and a top surface opposite the bottom surface;
drilling an array of blind holes from the top surface toward the bottom surface;
rolling a plurality of columns to form spiral threads thereon, respectively;
inserting the columns into the blind holes; and
driving the columns to move further into the blind holes of the base, during which the spiral threads threadedly engage in the blind holes of the base by self-tapping so that the columns are interferentially and intimately engaged with the base.

10. The heat sink as claimed in claim 9, wherein the columns each comprise a head and a terminated cone at opposite ends thereof, respectively.

11. The heat sink as claimed in claim 9, wherein the spiral thread of each column is between the head and the terminated cone.

12. The heat sink as claimed in claim 9, wherein the head defines a transverse groove therein, adapted for receiving a tool for facilitating to drive the columns to rotate.

13. A heat sink comprising:
a base having a bottom face for thermally engaging with an electronic component, and a top face opposite the bottom face; and
a plurality of fins each having a spiral thread threadedly engaging in the top face of the plate.

14. The heat sink as claimed in claim 13, wherein the spiral thread extends above the top face of the base a distance.

15. The heat sink as claimed in claim 14, wherein the spiral thread is a self-tapping screw thread.

16. The heat sink as claimed in claim 15, wherein the spiral thread extends to reach a top end of each of the fins. The heat sink as claimed in claim 16, wherein a groove is defined in the top end of each of the fins, adapted for receiving a tool for turning the fins.
Page 5 of 9
